(19) United States
(12) Patent Application Publication
(10) Pub. No.: US 2008/0050879 A1
(43) Pub. Date: Feb. 28, 2008

(54) METHODS OF FORMING METAL-CONTAINING GATE STRUCTURES

(75) Inventors: Cheng-Lung Hung, Hsinchu (TW); Peng-Fu Hsu, Hsinchu (TW); Jin Ying, Singapore (SG); Hun-Jan Tao, HsinChu (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/466,656

(22) Filed: Aug. 23, 2006

(51) Int. Cl. H01L 21/336

(52) U.S. Cl. 438/287; 438/591; 438/906

(57) ABSTRACT

A method of forming a metal-containing gate includes forming a high-k dielectric layer over a substrate. A process using an oxygen-containing solution is provided to process the high-k dielectric layer. A metal-containing layer is formed over the high-k dielectric layer. The high-k dielectric layer and metal-containing layer are patterned, thereby defining a gate structure.

### BACKGROUND OF THE INVENTION

1. Field of the Invention

The present invention relates to methods of forming semiconductor structures, and more particularly to methods of forming a metal-containing gate structure.

2. Description of the Related Art

With advances associated with electronic products, semiconductor technology has been widely applied in manufacturing memories, central processing units (CPUs), liquid crystal displays (LCDs), light emission diodes (LEDs), laser diodes and other devices or chip sets. In order to achieve high-integration and high-speed goals, dimensions of semiconductor integrated circuits continue to shrink. Various materials and techniques have been proposed to achieve these integration and speed goals and to overcome manufacturing obstacles associated therewith. High-k dielectric materials and gate metal gates, for example, have been proposed to replace traditional gate oxide materials and polysilicon gates to overcome obstacles confronted by the polysilicon gate transistors.

FIG. 1 shows a cross-sectional view of a prior art gate structure. In this figure, a gate oxide layer 110 and polysilicon gate layer 120 are sequentially formed over a substrate 100. Under an electrical operation, a positive voltage is applied to the polysilicon gate layer 120 and the substrate 100 is grounded or floating. The voltage drop between the polysilicon gate layer 120 and substrate 100 (i.e., the voltage drop across the gate oxide layer 110) results in leakage currents flowing through the gate oxide layer 110. In addition, due to its semiconductor characteristic, the polysilicon gate layer 120 will be partially depleted at the region 120a adjacent to the gate oxide layer 110, when the voltage is applied to the polysilicon gate layer 120. The depletion region 120a can lower the capacitance of the gate structure and affect electrical performance of the gate structure. These phenomena described above become more serious and destructive when the thicknesses of the gate oxide layer 110 and polysilicon gate layer 120 shrink to deep submicron levels.

To solve the depletion issue of the polysilicon gate 120 described above, high-k dielectric material and metal gate material has been used. Due to its high dielectric constant, a high-k gate dielectric layer having a physical thickness larger than a gate oxide layer provides an equivalent oxide thickness (EOT) that is the same as that of the gate oxide layer. The thick high-k gate dielectric layer can efficiently reduce a gate dielectric leakage current, compared with the gate oxide layer, when the same voltage drop is applied between the gate and substrate. Further, a metal gate layer has been used to replace the polysilicon gate layer. Since a metal gate layer is a conductor, the gate depletion issue set forth above is substantially eliminated.

Generally, defects and damage are inherently formed within a high-k dielectric layer. To cure or reduce defects and damage existing on the surface of, or within, the high-k dielectric layer, a post deposition annealing (PDA) process is performed between the steps of forming the high-k gate dielectric layer and forming the metal gate layer. The PDA process is performed within a chamber filled with oxygen and may efficiently remove defects and damage of the high-k dielectric layer.

From the foregoing, improved methods of forming metal gate structures are desired.

### SUMMARY OF THE INVENTION

In accordance with some exemplary embodiments, a method of forming a metal-containing gate includes forming a high-k dielectric layer over a substrate. A process using an oxygen-containing solution is provided to process the high-k dielectric layer. A metal-containing layer is formed over the high-k dielectric layer. The high-k dielectric layer and metal-containing layer are patterned, thereby defining a gate structure.

The above and other features will be better understood from the following detailed description of the preferred embodiments of the invention that is provided in connection with the accompanying drawings.

### BRIEF DESCRIPTION OF THE DRAWINGS

Following are brief descriptions of exemplary drawings. They are mere exemplary embodiments and the scope of the present invention should not be limited thereto.

FIG. 1 is a cross-sectional view of a prior art gate structure.

FIGS. 2A-2H are schematic cross-sectional views of an exemplary process of forming a gate structure.

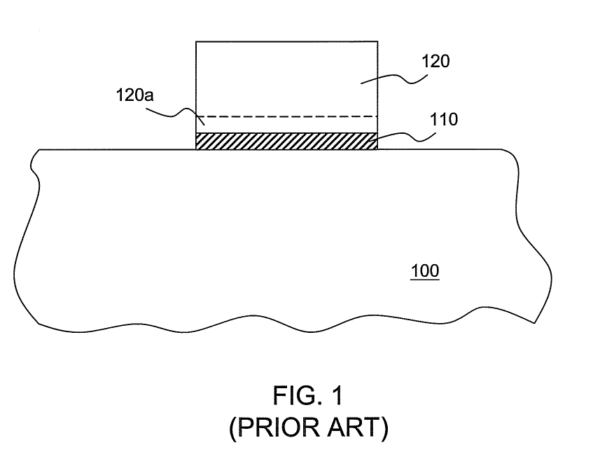

### DESCRIPTION OF THE PREFERRED EMBODIMENT

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

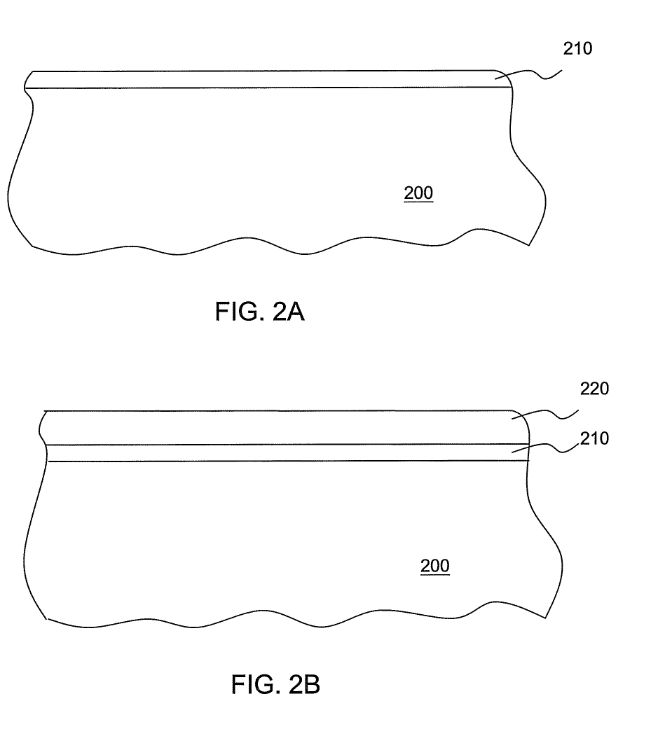

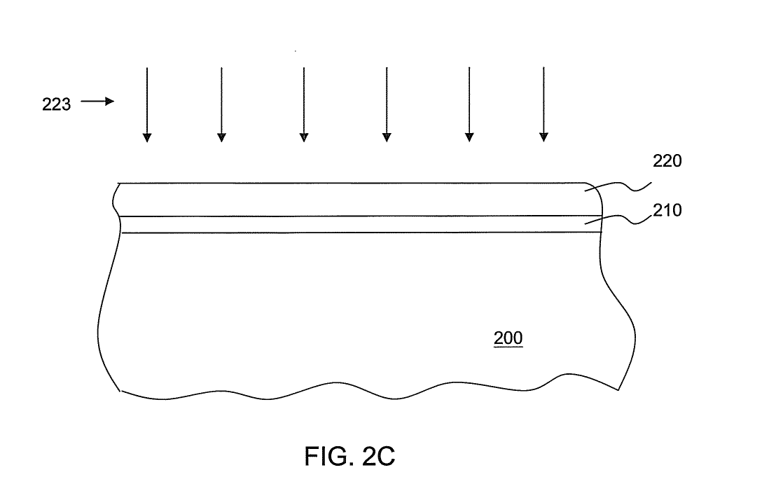

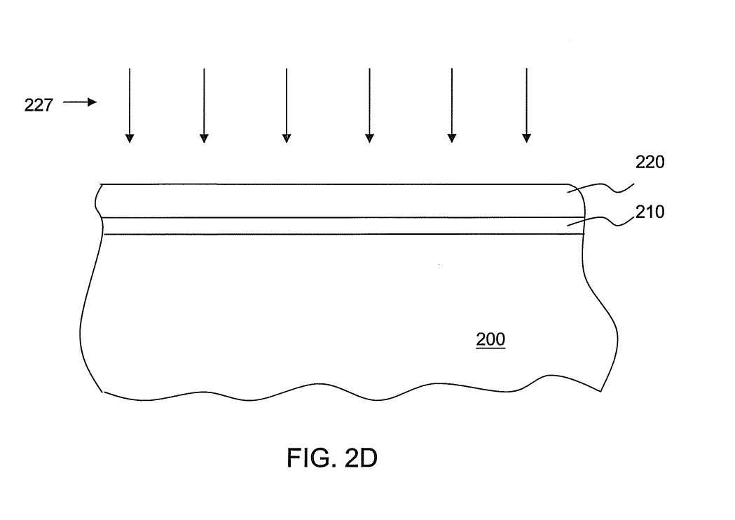

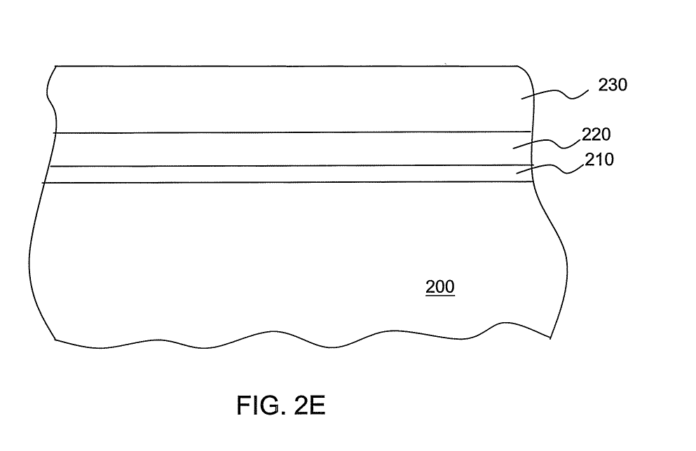

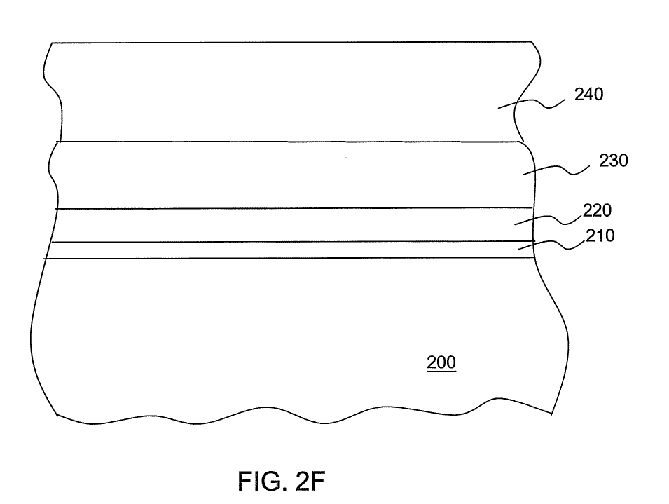

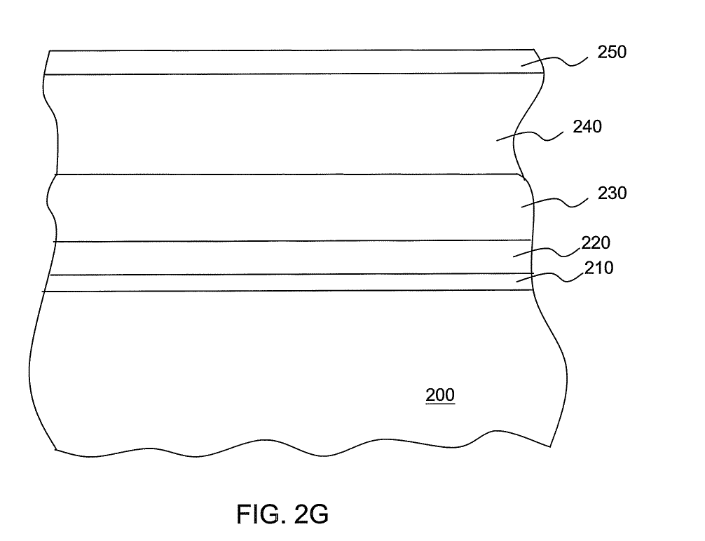

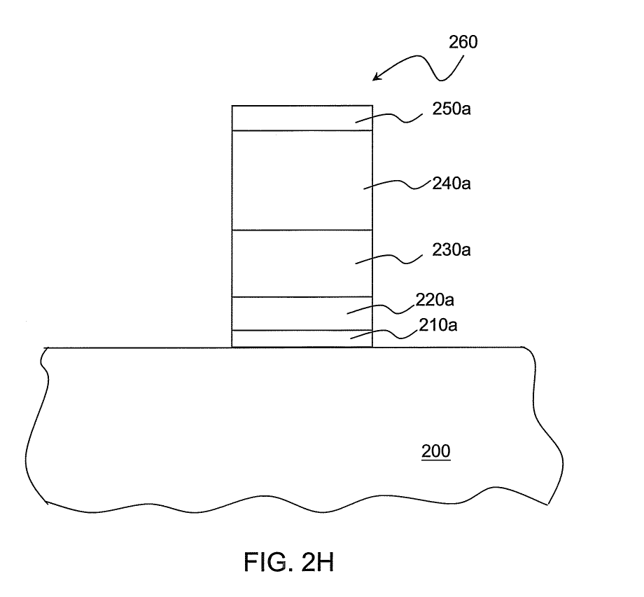

FIGS. 2A-2H are schematic cross-sectional views of an exemplary process of forming a gate structure.

Referring to FIG. 2A, a dielectric layer 210 is formed over a substrate 200. The substrate can be a P-type or N-type silicon substrate, III-V compound substrate, display substrate such as a substrate suitable for a liquid crystal display (LCD), plasma display, electro luminescence (EL) lamp display, a light emitting diode (LED) substrate (collectively referred to as, substrate 200), or the like, for example. The dielectric layer 210 may comprise, for example, an oxide layer, nitride layer, oxynitride layer or the like. The dielectric layer 210 is provided for allowing a subsequent high-k dielectric layer, e.g. dielectric layer 220, to be desirably formed over the substrate 200. For example, molecules of precursors provided for the formation of the high-k dielectric layer 220 can desirably attach to, or bond with, the dielectric layer 210. The dielectric layer 210 can be formed, for example, by a chemical process (e.g., standard clean 1 (SC1) process), thermal oxidation process, chemical vapor deposition process or other method that is able to form a thin dielectric layer. An SC1 process is cost-effective in view of its processing time and cost. For embodiments using 65-nm technology, the dielectric layer 210 is formed to be between about 4 Å and about 9 Å, preferably about 8.5 Å.

In some embodiments, the step of forming the dielectric layer 210 is optional if the high-k dielectric layer 220 can be desirably formed over the substrate 200 without the intervening dielectric layer 210.

As shown in FIG. 2B, a high-k dielectric layer 220 is formed over the dielectric layer 210 if the dielectric layer 210 is included as described above. The high-k dielectric layer 220 may have a permittivity of about 8 or more, and more preferably have a permittivity of about 10 or more, and even more preferably have a permittivity of about 20 or more. The high-k dielectric layer 220, due to its high dielectric constant, is formed to provide a desired equivalent oxide thickness (EOT), when a voltage drop is applied across the high-k dielectric layer 220. The high-k dielectric layer 220 may comprise a hafnium (Hf) containing dielectric layer, such as HfSiON, HfO₂, HfTaO, HfZrO, HfTaTiO, HfAlON, combinations thereof or the like. The high-k dielectric layer 220 may be formed, for example, by a CVD process, physical vapor deposition (PVD) process, atomic layer deposition (ALD) process, metal organic CVD (MOCVD) process, combinations thereof, or the like. For embodiments using 65-nm technology, the high-k dielectric layer 220 is formed to be between about 15 Å and about 45 Å, preferably about 30 Å.

Turning to FIG. 2C, an annealing process 223 processes the high-k dielectric layer 220. The annealing process 223 is provided to reduce and/or remove damage or defects existing on or within the high-k dielectric layer 220. In this art, the annealing process is referred to as “post deposition annealing” (PDA). The damage or defects within the high-k dielectric layer 220 may adversely affect electrical characteristics, e.g., dielectric constant or leakage resistance, of the high-k dielectric layer 220. The annealing process 223 may include a processing temperature ranging from about 400° C. to about 1,200° C., preferably about 500° C., and may be performed within a chamber having an environment of oxygen (O₂), nitrogen (N₂), hydrogen (H₂), deuterium (D₂), ammonia (NH₃), inert gas (e.g., argon (Ar)), combinations thereof, or the like. The annealing process may be performed by a furnace, rapid thermal annealing (RTA) apparatus, single-wafer thermal apparatus, combinations thereof, or the like.

As shown in FIG. 2D, a process 227 using an oxygen-containing solution is provided to treat the high-k dielectric layer 220. The process 227 may comprise a wet process, vapor treatment, combinations thereof, or the like. For example, the process 227 is performed by a wet bench, single wafer processing apparatus or the like. The substrate 200 having the high-k dielectric layer 220 formed thereover is immersed into the oxygen-containing solution introduced in a wet bench, or the oxygen-containing solution is dispensed or sprayed over the high-k dielectric layer 220 supported by a single wafer processing apparatus. The process 227 may also be performed in a chamber in which the oxygen-containing solution is vaporized, so as to process the high-k dielectric layer 220 configured within the chamber.

The process 227 may have a processing temperature between of about 20° C. and about 200° C. The oxygen-containing solution comprises hydrogen peroxide (H₂O₂), ozone (O₃), sulfuric acid (H₂SO₄), phosphoric acid (H₃PO₄), acetic acid (CH₃COOH), ammonia and hydrogen peroxide mixture (APM), sulfuric and hydrogen peroxide mixture (SPM) and hydrochloric and hydrogen peroxide mixture (HPM), combinations thereof or the like. In a preferred embodiment, the high-k dielectric layer 220 is processed by a single wafer process tool for about 120 seconds at a processing temperature of about 25° C., and the oxygen-containing solution is H₂O₂ having a concentration of about 31% in weight.

The process 227 provides a desired amount of oxygen that binds with dangling bonds or traps existing on the surface of, or within, the high-k dielectric layer 220 so as to reduce the level of the dangling bonds or traps. Removing or reducing the level of dangling bonds or traps improves electrical characteristics, e.g., capacitance or current leakage.

In some embodiments, the sequence of the processes 223 and 227 can be switched. In other embodiments, the annealing process 223 can optionally be omitted, if the process 227 can provide a desired amount of oxygen for removing or reducing dangling bonds or traps of the high-k dielectric layer 220. In the embodiments, the processing step 227 replaces the annealing step 223. Further, the omission of the annealing process 223 will reduce the thermal budget of forming a transistor.

Referring to FIG. 2E, a metal-containing layer 230 is formed over the high-k dielectric layer 220. The metal-containing layer 230 may comprise an N-type metal-containing layer which includes tantalum (Ta), for example; or a P-type metal-containing layer which includes tungsten (W), Molybdenum (Mo), ruthenium (Ru), combinations thereof or the like. The metal-containing layer 230 may be formed, for example, by a CVD process, PVD process, MOCVD process, ALD process, combinations thereof or the like. For embodiments using 65-nm technology, the metal-containing layer 230 is formed to be between about 10 Å and about 300 Å, preferably about 100 Å. Use of the metal-containing layer 230 can substantially eliminate a gate depletion concern as described above.

A cap layer 240 is then formed over the metal-containing layer 230 as shown in FIG. 2F. The cap layer 240 is formed for preventing oxidation of the metal-containing layer 230 resulting from a subsequent thermal process, such as an annealing process. Oxidation of the metal-containing layer 230 may increase the resistance thereof, adversely affecting electrical characteristics, such as capacitance or current leakage, of the metal-containing layer 230.

The cap layer 240 may comprise, for example, a tantalum nitride (TaN) layer, titanium nitride (TiN) layer, TaSiN layer, combinations thereof or the like, and may be formed by, for example, a CVD process, PVD process, MOCVD process, ALD process or the like. For embodiments using 65-nm technology, the cap layer 240 is between about 10 Å and about 1,000 Å in thickness. The cap layer 240 may prevent metal oxidation occurring to the metal-containing layer 230. It may depend on material property of the metal-containing layer 230. For example, the metal-containing layer 230 is a P-type layer, e.g., including material of Mo, W and/or Ru. This P-type metal-containing layer is not stable and is vulnerable to metal oxidation. For embodiments using an N-type metal-containing layer, e.g., including a Ta material, this N-type metal-containing layer 230 is stable and the cap layer 240 may be optionally omitted. In other words, the cap layer 240 is optional if the oxidation of the metal-containing layer 230 is not a concern within a given manufacturing process.

As shown in FIG. 2G, a material layer 250 is formed over the cap layer 240, if the cap layer 240 is included. The material layer 250 may comprise, for example, a polysilicon layer, amorphous silicon layer, P-type silicon layer, N-type silicon, combinations thereof or the like. The material layer 250 is provided to prevent contamination resulting from the metal-containing layer 230. In some embodiments, the material layer 250 is provided to achieve a desired height of the gate structure. For example, a polysilicon gate structure is higher than a metal-containing gate structure, if they are provided to form transistors having the same gate feature size, e.g., gate length. A manufacturing process of forming a transistor having a polysilicon gate structure may be used to form a transistor having a metal-containing gate structure. However, due to the different heights of the polysilicon and metal-containing gates, the manufacturing process for the polysilicon gate cannot be directly applied without modification to form a metal-containing gate transistor. One or more steps of the manufacturing process, e.g., photolithographic or etch steps, should be modified due to a different topography encountered when forming the metal-containing gate. By adding the material layer 250, modification of the manufacturing process can be substantially eased. The material layer 250 can be formed, for example, by a CVD process. For embodiments using 65-nm technology, the material layer 250 is between about 400 Å and about 1,000 Å in thickness, preferably about 1,000 Å. In some embodiments, the material layer 250 may optionally be omitted if contamination and/or gate height difference set forth above are not concerns.

Referring to FIG. 2H, a gate structure 260, including the dielectric layer 210a, high-k dielectric layer 220a, metal-containing layer 230a, cap layer 240a and material layer 250a, is sequentially formed over the substrate 200. In order to form the gate structure 260, a photoresist pattern (not shown) corresponding to the patterned layers 210a-250a is formed over the structure shown in FIG. 2G by a photolithographic process, for example. An etch process, which may include multiple etch steps corresponding to the layers 210-250, is performed for partially removing the layers 210-250, thereby forming the gate structure 260 as shown in FIG. 2H. As described above, the layers 210, 240 and/or 250 are optional. The etch process may be modified corresponding to the variation of the gate structure 260. After the etch process, the patterned photoresist is removed by a photolithographic removal process, for example.

Though dimensions of the layers 210a-250a of the gate structure 260 are shown for an example using 65-nm technology, the present invention, however, is not limited thereto. Dimensions of these layers 210-250a may vary in accordance with the feature size of the semiconductor technology. One of ordinary skill in the art can readily modify the dimensions of these layers to achieve a desired gate structure.

Although the present invention has been described in terms of exemplary embodiments, it is not limited thereto. Rather, the appended claims should be construed broadly to include other variants and embodiments of the invention, which may be made by those skilled in the field of this art without departing from the scope and range of equivalents of the invention.

What is claimed is:

1. A method of forming a metal-containing gate, comprising the steps of:
forming a high-k dielectric layer over a substrate;
processing the high-k dielectric layer with an oxygen-containing solution;
forming a metal-containing layer over the high-k dielectric layer; and
patterning the high-k dielectric layer and metal-containing layer, thereby defining a gate structure.

2. The method of claim 1, wherein the oxygen-containing solution comprises hydrogen peroxide.

3. The method of claim 1 further comprising forming a dielectric layer between the high-k dielectric layer and substrate.

4. The method of claim 3, wherein the step of forming the dielectric layer comprises a standard clean 1 (SC1) process.

5. The method of claim 1, wherein the high-k dielectric layer comprises a hafnium (Hf) containing dielectric layer.

6. The method of claim 1, wherein the processing step using the oxygen-containing solution has a processing temperature between about 20° C. and about 200° C.

7. The method of claim 1, wherein the oxygen-containing solution comprises at least one of a group consisting of hydrogen peroxide (H₂O₂), ozone (O₃), sulfuric acid (H₂SO₄), phosphoric acid (H₃PO₄), acetic acid (CH₃COOH), ammonia and hydrogen peroxide mixture (APM), sulfuric and hydrogen peroxide mixture (SPM) and hydrochloric and hydrogen peroxide mixture (HPM).

8. The method of claim 1 further comprising annealing the high-k dielectric layer.

9. The method of claim 1, wherein the metal-containing layer comprises at least one component from the group consisting of tantalum (Ta), tungsten (W), molybdenum (Mo) and ruthenium (Ru).

10. The method of claim 1 further comprising forming a cap layer over the metal-containing layer.

11. A method of forming a metal-containing gate, comprising the steps of:
forming a dielectric layer over a substrate;
forming a high-k dielectric layer over the dielectric layer;
processing the high-k dielectric layer with an oxygen-containing solution;
forming a metal-containing layer over the high-k dielectric layer;
forming a cap layer over the metal-containing layer; and
patterning the dielectric layer, high-k dielectric layer, metal-containing layer and cap layer, thereby defining a gate structure.

12. The method of claim 11, wherein the step of forming the dielectric layer comprises a standard clean 1 (SC1) process.

13. The method of claim 11, wherein the high-k dielectric layer comprises a hafnium (Hf) containing dielectric layer.

14. The method of claim 11, wherein the processing step using the oxygen-containing solution has a processing temperature between of about 20° C. and about 200° C.

15. The method of claim 11, wherein the oxygen-containing solution comprises at least one of a group consisting of hydrogen peroxide (H₂O₂), ozone (O₃), sulfuric acid (H₂SO₄), phosphoric acid (H₃PO₄), acetic acid (CH₃COOH), ammonia and hydrogen peroxide mixture (APM), sulfuric and hydrogen peroxide mixture (SPM) and hydrochloric and hydrogen peroxide mixture (HPM).

16. The method of claim 11, wherein the metal-containing layer comprises at least one component of a group consisting of tantalum (Ta), tungsten (W), molybdenum (Mo) and ruthenium (Ru).

17. A method of forming a metal-containing gate, comprising the steps of:
forming an oxide layer over a substrate;
forming a hafnium (Hf) containing dielectric layer over the oxide layer;
processing the Hf-containing dielectric layer with an oxygen-containing solution;
forming a metal-containing layer over the Hf-containing dielectric layer;
forming a cap layer over the metal-containing layer;
forming a material layer over the cap layer; and
patterning the oxide layer, Hf-containing dielectric layer, metal-containing layer, cap layer and material layer, thereby defining a gate structure.

18. The method of claim 17, wherein the step of processing the high-k dielectric layer has a processing temperature between of about 20° C. and about 200° C.

19. The method of claim 17, wherein the oxygen-containing solution comprises at least one from the group consisting of hydrogen peroxide (H₂O₂), ozone (O₃), sulfuric acid (H₂SO₄), phosphoric acid (H₃PO₄), acetic acid (CH₃COOH), ammonia and hydrogen peroxide mixture (APM), sulfuric and hydrogen peroxide mixture (SPM) and hydrochloric and hydrogen peroxide mixture (HPM).

20. The method of claim 17, wherein the metal-containing layer comprises at least one component of a group consisting of tantalum (Ta), tungsten (W), molybdenum (Mo) and ruthenium (Ru).
